(19) United States
(12) Patent Application Publication
(10) Pub. No.: US 2026/0331439 A1
(43) Pub. Date: Oct. 22, 2026

(54) ELECTROSTATIC CHUCK AND SUBSTRATE FIXING DEVICE

(71) Applicant: SHINKO ELECTRIC INDUSTRIES CO., LTD., Nagano-shi (JP)

(72) Inventors: Ken Sato, Nagano (JP); Shun Takagi, Nagano (JP); Hiroshi Ishii, Nagano (JP)

(21) Appl. No.: 19/468,214

(22) Filed: Feb. 3, 2026

(30) Foreign Application Priority Data
Feb. 4, 2025 (JP) 2025-016757

(51) Int. Cl. H01J 37/32; H10P 72/72

(52) U.S. Cl. CPC H01J 37/32715; H10P 72/722; H01J 2237/2007

(57) ABSTRACT

An electrostatic chuck includes a first ceramic substrate, a conductor pattern embedded in the first ceramic substrate, and a second ceramic substrate bonded to an upper surface of the first ceramic substrate. The first ceramic substrate contains aluminum oxide at first purity. The second ceramic substrate contains aluminum oxide at second purity higher than the first purity.

### CROSS-REFERENCE TO RELATED APPLICATIONS

This application claims priority from Japanese Patent Application No. 2025-016757, filed on Feb. 4, 2025, the entire content of which is incorporated herein by reference.

### TECHNICAL FIELD

The present invention relates to an electrostatic chuck and a substrate fixing device.

### BACKGROUND ART

A substrate fixing device includes a base plate and an electrostatic chuck fixed to the base plate. The electrostatic chuck includes a ceramic substrate, and electrodes and a heater embedded in the ceramic substrate. When the substrate fixing device is used, the ceramic substrate is worn due to exposure to plasma or the like, and the flatness of an upper surface of the ceramic substrate decreases. Therefore, in the related art, the entire substrate fixing device is replaced, or the electrostatic chuck is replaced while reusing the base plate.

### SUMMARY OF INVENTION

In recent years, there has been an increasing demand for reducing running cost of the substrate fixing device.

An object of the present disclosure is to provide an electrostatic chuck and a substrate fixing device capable of reducing running cost.

According to one aspect of the present disclosure, an electrostatic chuck includes a first ceramic substrate, a conductor pattern embedded in the first ceramic substrate, and a second ceramic substrate bonded to an upper surface of the first ceramic substrate. The first ceramic substrate contains aluminum oxide at first purity. The second ceramic substrate contains aluminum oxide at second purity higher than the first purity.

According to the present disclosure, the running cost can be reduced.

### BRIEF DESCRIPTION OF DRAWINGS

FIG. 1A is a plan view illustrating a substrate fixing device according to a first embodiment.

FIG. 1B is a cross-sectional view illustrating the substrate fixing device according to the first embodiment.

FIG. 2A is a cross-sectional view illustrating a method for manufacturing the substrate fixing device according to the first embodiment.

FIG. 2B is a cross-sectional view illustrating the method for manufacturing the substrate fixing device according to the first embodiment.

FIG. 2C is a cross-sectional view illustrating the method for manufacturing the substrate fixing device according to the first embodiment.

FIG. 3A is a cross-sectional view (part 1) illustrating a maintenance method of the substrate fixing device according to the first embodiment.

FIG. 3B is a cross-sectional view (part 1) illustrating the maintenance method of the substrate fixing device according to the first embodiment.

FIG. 4A is a cross-sectional view (part 2) illustrating the maintenance method of the substrate fixing device according to the first embodiment.

FIG. 4B is a cross-sectional view (part 2) illustrating the maintenance method of the substrate fixing device according to the first embodiment.

FIG. 5 is a cross-sectional view illustrating a substrate fixing device according to a second embodiment.

FIG. 6A is a cross-sectional view illustrating a method for manufacturing the substrate fixing device according to the second embodiment.

FIG. 6B is a cross-sectional view illustrating the method for manufacturing the substrate fixing device according to the second embodiment.

FIG. 6C is a cross-sectional view illustrating the method for manufacturing the substrate fixing device according to the second embodiment.

FIG. 7A is a cross-sectional view (part 1) illustrating the maintenance method of the substrate fixing device according to the second embodiment.

FIG. 7B is a cross-sectional view (part 1) illustrating the maintenance method of the substrate fixing device according to the second embodiment.

FIG. 8A is a cross-sectional view (part 2) illustrating the maintenance method of the substrate fixing device according to the second embodiment.

FIG. 8B is a cross-sectional view (part 2) illustrating the maintenance method of the substrate fixing device according to the second embodiment.

### DESCRIPTION OF EMBODIMENTS

Hereinafter, embodiments of the present disclosure will be specifically described with reference to the accompanying drawings. It should be noted that, in the present specification and the drawings, components having substantially the same functional configuration are denoted by the same reference signs, and redundant description may be omitted.

### First Embodiment

A first embodiment will be described. The first embodiment relates to a substrate fixing device.

### Structure of Substrate Fixing Device

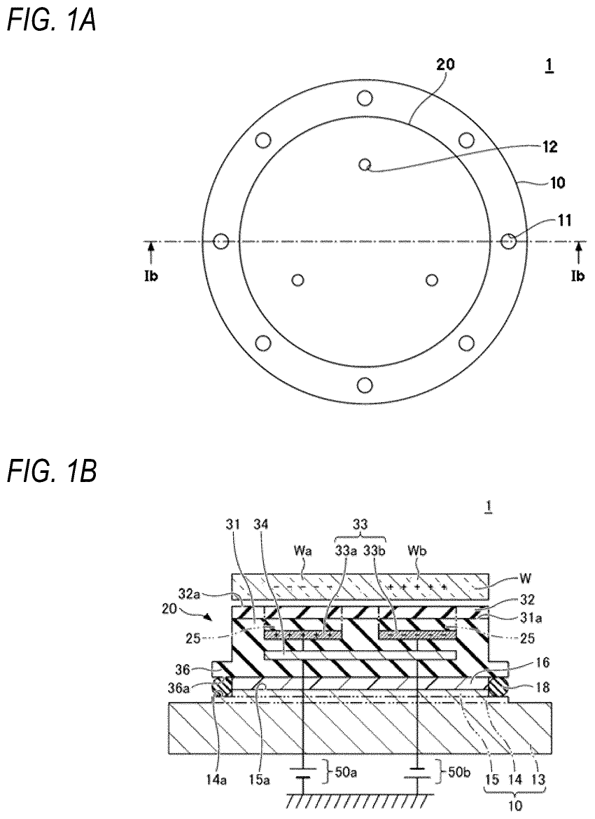

A structure of the substrate fixing device according to the first embodiment will be described. FIGS. 1A and 1B are views illustrating the substrate fixing device according to the first embodiment. FIG. 1A is a plan view, and FIG. 1B is a cross-sectional view. FIG. 1B is a cross-sectional view taken along line Ib-Ib in FIG. 1A.

As illustrated in FIGS. 1A and 1B, the substrate fixing device 1 according to the first embodiment includes a base plate 10 and an electrostatic chuck 20. The substrate fixing device 1 suctions and holds a substrate W (for example, a semiconductor wafer or the like), which is a suction target, by the electrostatic chuck 20.

The base plate 10 and the electrostatic chuck 20 are formed in a circular shape in a plan view. That is, the base plate 10 and the electrostatic chuck 20 are formed in a disk shape. The base plate 10 is exposed around the electrostatic chuck 20. In a peripheral portion of the base plate 10, attachment holes 11 for attachment to a chamber of a semiconductor manufacturing device are arranged along the peripheral portion. In FIG. 1B, the attachment hole 11 is omitted. Further, the electrostatic chuck 20 and the base plate 10 have a plurality of (three in FIG. 1A) lift pin openings 12 in a central portion thereof. A lift pin (not illustrated) that moves the substrate W in an up-down direction is inserted into the opening 12. By raising the substrate W from the electrostatic chuck 20 by the lift pins, the substrate W can be automatically transferred by a transfer device.

The “plan view” refers to a view of an object from a normal direction of an upper surface of the base plate 10, and the “planar shape” refers to a shape of the object viewed from the normal direction of the upper surface of the base plate 10.

The base plate 10 is a member for mounting the electrostatic chuck 20. The thickness of the base plate 10 is, for example, 20 mm or more and 40 mm or less. The base plate 10 is formed of, for example, a metal material such as aluminum or a super hard alloy, a composite material of the metal material and a ceramic material, or the like, and can be used as an electrode or the like for controlling plasma. For example, in terms of availability, ease of processing, good thermal conductivity, and the like, it is preferable to use aluminum or an alloy thereof and to perform an alumite treatment (insulating layer formation) on a surface thereof.

The base plate 10 includes a base portion 13, a first protrusion 14, and a second protrusion 15. The base portion 13 has a disk shape, the first protrusion 14 protrudes upward in a disk shape from the base portion 13, and the second protrusion 15 protrudes upward in a disk shape from the first protrusion 14. The base portion 13, the first protrusion 14, and the second protrusion 15 are disposed concentrically with each other in the plan view. The second protrusion 15 has an upper surface 15a, and the first protrusion 14 has an upper surface 14a exposed from the second protrusion 15.

For example, by supplying a predetermined high frequency power to the base plate 10, it is possible to control energy for causing generated ions or the like in a plasma state to collide with the substrate W suctioned on the electrostatic chuck 20, and to effectively perform etching processing of the substrate W.

A gas supply passage for introducing an inert gas for cooling the substrate W suctioned on the electrostatic chuck 20 may be provided inside the base plate 10. When an inert gas such as helium (He) or argon (Ar) is introduced into the gas supply passage from the outside of the substrate fixing device 1 and the inert gas is supplied to a back surface of the substrate W suctioned on the electrostatic chuck 20, the substrate W can be cooled.

The electrostatic chuck 20 suctions and holds the substrate W, which is the suction target. A planar shape of the electrostatic chuck 20 is formed according to a shape of the substrate W, and is, for example, circular. The diameter of the wafer, which is the suction target of the electrostatic chuck 20, is, for example, 203.2 mm (8 inches), 304.8 mm (12 inches), or 457.2 mm (18 inches).

The electrostatic chuck 20 includes a first ceramic substrate 31, a second ceramic substrate 32, an electrostatic electrode 33, and a heating element 34. The electrostatic chuck 20 is, for example, a Johnsen-Rahbek type electrostatic chuck. However, the electrostatic chuck 20 may be a Coulomb force type electrostatic chuck.

The first ceramic substrate 31 has a disk shape. The first ceramic substrate 31 has a flange portion 36 protruding laterally formed at a lower end (on a base plate 10 side). The first ceramic substrate 31 is made of ceramic. The first ceramic substrate 31 contains aluminum oxide at first purity. The first purity is, for example, less than 99 mass %, and more specifically, 94 mass % or more and 96 mass % or less. The thickness of the first ceramic substrate 31 is, for example, 5 mm or more and 10 mm or less.

The electrostatic electrode 33 is a thin-film electrode formed of a conductor pattern, and is incorporated in the first ceramic substrate 31. In the present embodiment, the electrostatic electrode 33 is of a bipolar type and includes a first electrostatic electrode 33a and a second electrostatic electrode 33b. As the electrostatic electrode 33, a unipolar type including one electrostatic electrode may be used. A distance between the electrostatic electrode 33 and an upper surface 31a of the first ceramic substrate 31 is, for example, 0.1 mm or more and 0.2 mm or less.

The first electrostatic electrode 33a is connected to a positive electrode side of a power supply 50a provided outside the substrate fixing device 1. The second electrostatic electrode 33b is connected to a negative electrode side of a power supply 50b provided outside the substrate fixing device 1. A negative electrode side of the power supply 50a and a positive electrode side of the power supply 50b are connected outside the substrate fixing device 1, and a connection point is a ground potential.

The heating element 34 is a heater that is incorporated in the first ceramic substrate 31 and generates heat when a current flows. The heating element 34 is disposed below (at a base plate 10 side of) the first electrostatic electrode 33a and the second electrostatic electrode 33b. The heating element 34 is a conductor formed in a film shape. The heating element 34 is provided as a plurality of heater electrodes capable of independently controlling heating of a plurality of regions (heater zones) of the first ceramic substrate 31 in a plane. The heating element 34 may be provided as one heater electrode. The heating element 34 can be formed of, for example, a material similar to that of the electrostatic electrode 33.

The second ceramic substrate 32 is bonded to the first ceramic substrate 31. The second ceramic substrate 32 is in direct contact with the first ceramic substrate 31. The second ceramic substrate 32 is made of ceramic. The second ceramic substrate 32 contains aluminum oxide at second purity higher than the first purity. The second purity is, for example, 99% by mass or more. The thickness of the second ceramic substrate 32 is, for example, 0.1 mm or more and 0.5 mm or less. An upper surface of the second ceramic substrate 32 is a placement surface 32a on which the suction target is placed.

A positive (+) voltage is applied from the power supply 50a to the first electrostatic electrode 33a, and a negative (−) voltage is applied from the power supply 50b to the second electrostatic electrode 33b. Accordingly, the first electrostatic electrode 33a is charged with the positive (+) charge, and the second electrostatic electrode 33b is charged with the negative (−) charge. Accordingly, the negative (−) charge is induced in a portion Wa of the substrate W corresponding to the first electrostatic electrode 33a, and the positive (+) charge is induced in a portion Wb of the substrate W corresponding to the second electrostatic electrode 33b.

In the electrostatic chuck 20, the substrate W and the electrostatic electrode 33 can be regarded as two electrodes of a capacitor, and a ceramic portion 25 between the substrate W and the electrostatic electrode 33 of the electrostatic chuck 20 can be regarded as a dielectric of the capacitor. Then, in the capacitor, the substrate W is electrostatically absorbed on the electrostatic chuck 20 by Coulomb force generated between the electrostatic electrode 33 and the substrate W via the ceramic portion 25. A suction-holding force increases as the voltage applied to the electrostatic electrode 33 increases.

Further, when a current is supplied to the heating element 34 from a power supply provided outside the substrate fixing device 1, the heating element 34 generates heat to heat the electrostatic chuck 20. The substrate W is controlled to a predetermined temperature by the temperature of the electrostatic chuck 20. A heating temperature of the electrostatic chuck 20 is set within a range of 50 °C to 200 °C, for example, 150 °C.

The electrostatic chuck 20 is provided on the upper surface 15a of the second protrusion 15 of the base plate 10 via an adhesive layer 16. The base plate 10 and the first ceramic substrate 31 are in contact with the adhesive layer 16, and the first ceramic substrate 31 is between the base plate 10 and the second ceramic substrate 32. The adhesive layer 16 is, for example, a silicone-based adhesive. The thickness of the adhesive layer 16 is, for example, 0.1 mm or more and 2.0 mm or less. The adhesive layer 16 has an effect of adhering the base plate 10 and the electrostatic chuck 20 and reducing thermal stress generated due to a difference in thermal expansion coefficient between the electrostatic chuck 20 made of ceramic and the base plate 10 made of aluminum. The electrostatic chuck 20 may be fixed to the base plate 10 by screws.

An O-ring 18 is provided between a lower surface 36a of the flange portion 36 and the upper surface 14a of the first protrusion 14. The O-ring 18 is in contact with the lower surface 36a of the flange portion 36 and the upper surface 14a of the first protrusion 14 and covers the adhesive layer 16 from a lateral side. The O-ring 18 can reduce deterioration of the adhesive layer 16 due to exposure to plasma.

### Method for Manufacturing Substrate Fixing Device

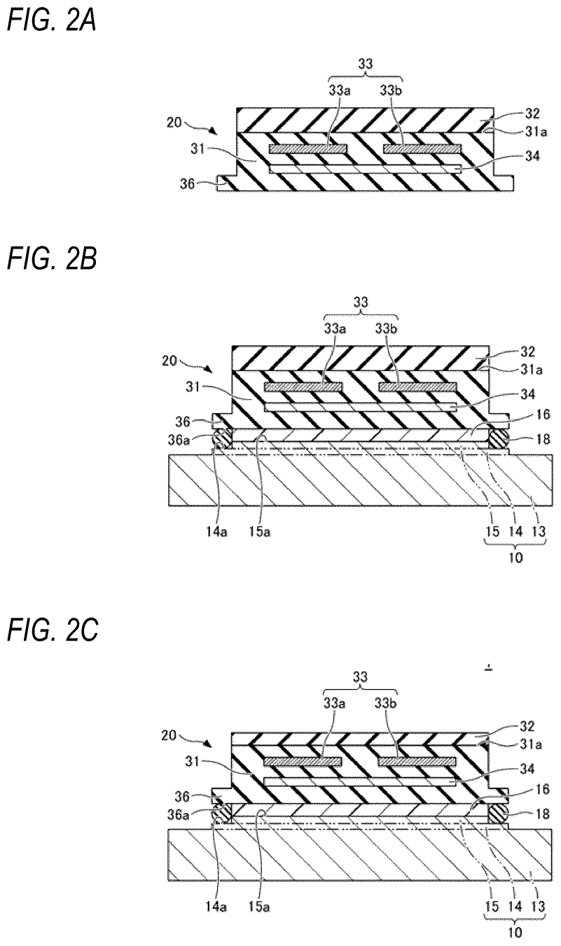

Next, a method for manufacturing the substrate fixing device 1 will be described. FIGS. 2A to 2C are cross-sectional views illustrating the method for manufacturing the substrate fixing device according to the first embodiment.

First, as illustrated in FIG. 2A, the second ceramic substrate 32 and the first ceramic substrate 31 that incorporates the electrostatic electrode 33 and the heating element 34 are prepared.

In the preparation of the first ceramic substrate 31 incorporating the electrostatic electrode 33 and the heating element 34, a green sheet on which no conductor pattern is formed, a green sheet on which a conductor pattern serving as the electrostatic electrode 33 is formed, and a green sheet on which a conductor pattern serving as the heating element 34 is formed are laminated and fired. These green sheets may contain a sintering aid. In the preparation of the second ceramic substrate 32, the green sheet not containing the sintering aid is fired. The second ceramic substrate 32 having a thickness greater than a final thickness is prepared. For example, the second ceramic substrate 32 having a thickness of 1 mm or more and 3 mm or less is prepared. Next, the second ceramic substrate 32 is bonded to the upper surface 31a of the first ceramic substrate 31 by diffusion bonding. In this way, the electrostatic chuck 20 is obtained.

The base plate 10 is prepared, and as illustrated in FIG. 2B, for example, the electrostatic chuck 20 is adhered to the upper surface 15a of the second protrusion 15 of the base plate 10 using a silicone-based adhesive to form the adhesive layer 16. The O-ring 18 is provided between the lower surface 36a of the flange portion 36 and the upper surface 14a of the first protrusion 14.

Next, as illustrated in FIG. 2C, the upper surface of the second ceramic substrate 32 is grinded to set the thickness of the second ceramic substrate 32 to 0.1 mm or more and 0.5 mm or less.

In this way, the substrate fixing device 1 can be manufactured.

### Maintenance Method of Substrate Fixing Device

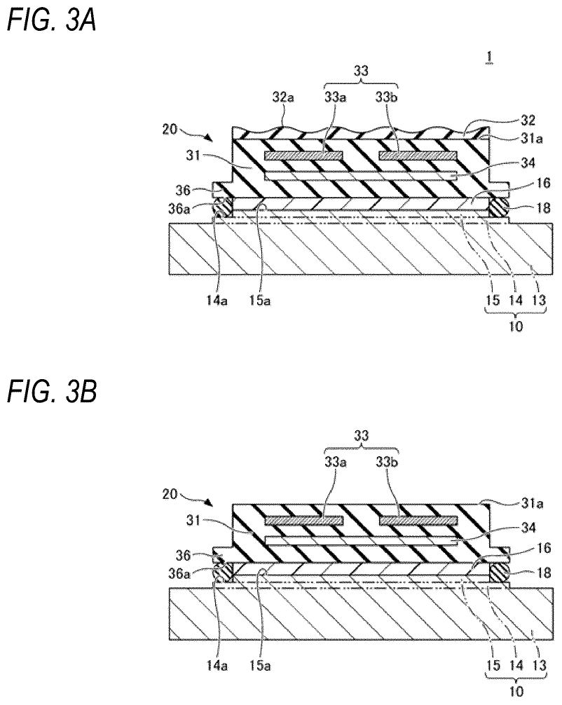

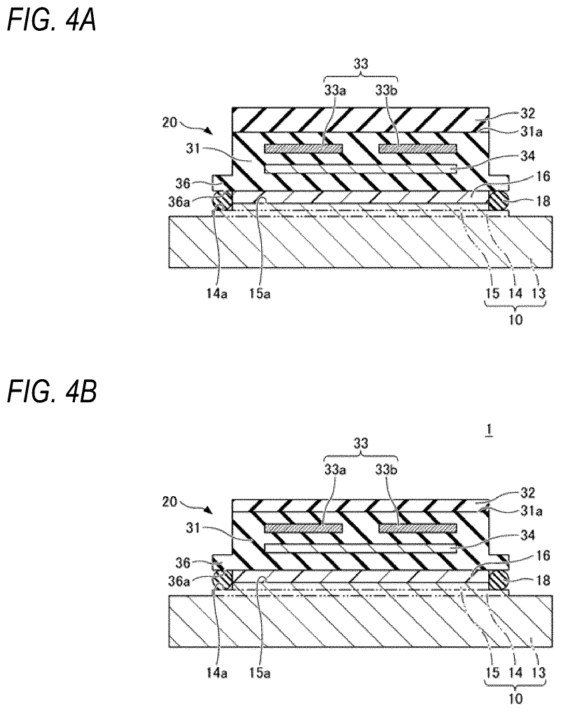

Next, a maintenance method of the substrate fixing device 1 will be described. FIGS. 3A to 4B are cross-sectional views illustrating the maintenance method of the substrate fixing device according to the first embodiment.

When the substrate fixing device 1 is used, the second ceramic substrate 32 is worn due to exposure to plasma or the like, and as illustrated in FIG. 3A, the flatness of the placement surface 32a, which is the upper surface of the second ceramic substrate 32, decreases. Therefore, for example, when the thickness of the second ceramic substrate 32 is reduced to a predetermined thickness or when the substrate fixing device 1 is used a predetermined number of times or for a predetermined time, the second ceramic substrate 32 is replaced.

Specifically, first, as illustrated in FIG. 3B, the second ceramic substrate 32 is grinded to expose the upper surface 31a of the first ceramic substrate 31.

Next, as illustrated in FIG. 4A, the new second ceramic substrate 32 is bonded to the upper surface 31a of the first ceramic substrate 31 by the diffusion bonding. The new second ceramic substrate 32 to be bonded is thicker than the final thickness. For example, the new second ceramic substrate 32 having a thickness of 1 mm or more and 3 mm or less is bonded.

Next, as illustrated in FIG. 4B, the upper surface of the second ceramic substrate 32 is grinded to set the thickness of the second ceramic substrate 32 to 0.1 mm or more and 0.5 mm or less.

In this way, the second ceramic substrate 32 can be replaced and the maintenance of the substrate fixing device 1 can be performed.

In the substrate fixing device 1, since the second ceramic substrate 32 contains aluminum oxide at the second purity higher than the first purity of the first ceramic substrate 31, plasma resistance of the second ceramic substrate 32 is high, and the second ceramic substrate 32 is less likely to be worn. Therefore, frequency of replacement of the second ceramic substrate 32 can be reduced, and running cost can be reduced.

When the second ceramic substrate 32 is worn, as described above, only the second ceramic substrate 32 needs to be replaced, and frequency of replacement of the first ceramic substrate 31 may be lower than the frequency of replacement of the second ceramic substrate 32. Therefore, the frequency of replacement of the first ceramic substrate 31 having a high added value and incorporating the electrostatic electrode 33 and the heating element 34 can be reduced, and the running cost can also be reduced in this respect.

Further, since the second ceramic substrate 32 does not incorporate an electrostatic electrode and a heating element, the second ceramic substrate 32 does not need to have a thickness for incorporating them. In particular, when the thickness of the second ceramic substrate 32 is 0.5 mm or less, the time required for grinding at the time of replacement is short. When the thickness of the second ceramic substrate 32 is less than 0.1 mm, a time until the second ceramic substrate 32 disappears due to wear may be excessively shortened.

Further, since the second ceramic substrate 32 does not incorporate an electrostatic electrode and a heating element, a wiring connected thereto and a hole for the wiring are unnecessary in the second ceramic substrate 32, and the uniformity of the heat transfer efficiency of the second ceramic substrate 32 is high.

Further, it is also possible to use the base plate 10 and the second ceramic substrate 32 as general-purpose components, while changing only the first ceramic substrate 31 according to the application. For example, it is also possible to use the first ceramic substrate 31 in which the pattern of the electrostatic electrode 33 varies depending on the type of the suction target.

By setting the first purity of aluminum oxide of the first ceramic substrate 31 to 99 mass % or more, the first ceramic substrate 31 and the second ceramic substrate 32 may be formed of one ceramic substrate. However, in order to obtain a ceramic substrate in which the purity of aluminum oxide is 99 mass % or more, the green sheet not containing the sintering aid is used, but it is difficult to simultaneously fire the conductor pattern serving as the electrostatic electrode 33 and the conductor pattern serving as the heating element 34. Therefore, it is difficult to form the first ceramic substrate 31 and the second ceramic substrate 32 from one ceramic substrate in which the purity of aluminum oxide is 99 mass % or more.

### Second Embodiment

A second embodiment will be described. The second embodiment is different from the first embodiment mainly in the configuration of the electrostatic chuck 20.

### Structure of Substrate Fixing Device

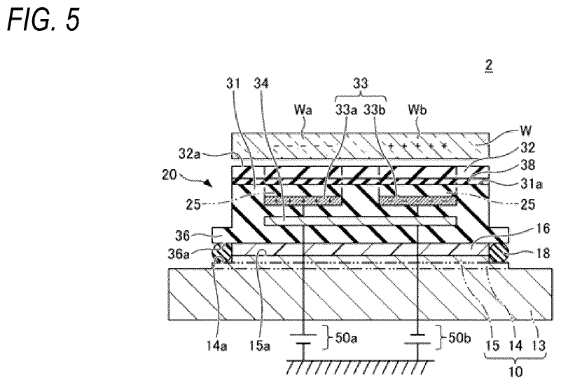

A structure of a substrate fixing device according to the second embodiment will be described. FIG. 5 is a cross-sectional view illustrating a substrate fixing device according to a second embodiment.

As illustrated in FIG. 5, in a substrate fixing device 2 according to the second embodiment, the electrostatic chuck 20 includes the first ceramic substrate 31, the second ceramic substrate 32, the electrostatic electrode 33, the heating element 34, and a bonding layer 38. The bonding layer 38 contains a glass fiber and an epoxy resin, and bonds the first ceramic substrate 31 and the second ceramic substrate 32. The bonding layer 38 has a thermal conductivity of, for example, 5 W/m·K or more. The thermal conductivity of the bonding layer 38 may be 5 W/m·K or more and 10 W/m·K or less, or 6 W/m·K or more and 8 W/m·K or less.

Other configurations of the substrate fixing device 2 according to the second embodiment are the same as those of the substrate fixing device 1 according to the first embodiment.

### Method for Manufacturing Substrate Fixing Device

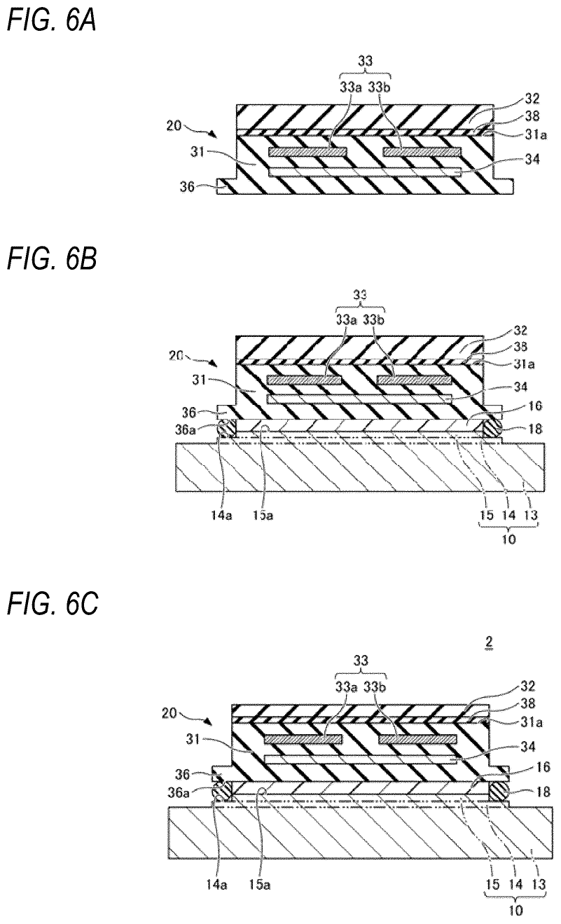

Next, a method for manufacturing the substrate fixing device 2 will be described. FIGS. 6A to 6C are cross-sectional views illustrating the method for manufacturing the substrate fixing device according to the second embodiment.

First, as illustrated in FIG. 6A, the second ceramic substrate 32 and the first ceramic substrate 31 that incorporates the electrostatic electrode 33 and the heating element 34 are prepared. Next, the second ceramic substrate 32 is bonded to the upper surface 31a of the first ceramic substrate 31 using a bonding sheet containing a glass fiber and an epoxy resin. In this way, the bonding layer 38 is formed, and the electrostatic chuck 20 is obtained.

Similarly to the first embodiment, the base plate 10 is prepared, and as illustrated in FIG. 6B, for example, the electrostatic chuck 20 is adhered to the upper surface 15a of the second protrusion 15 of the base plate 10 using a silicone-based adhesive to form the adhesive layer 16. The O-ring 18 is provided between the lower surface 36a of the flange portion 36 and the upper surface 14a of the first protrusion 14.

Next, similarly to the first embodiment, as illustrated in FIG. 6C, the upper surface of the second ceramic substrate 32 is grinded to set the thickness of the second ceramic substrate 32 to 0.1 mm or more and 0.5 mm or less.

In this way, the substrate fixing device 2 can be manufactured.

### Maintenance Method of Substrate Fixing Device

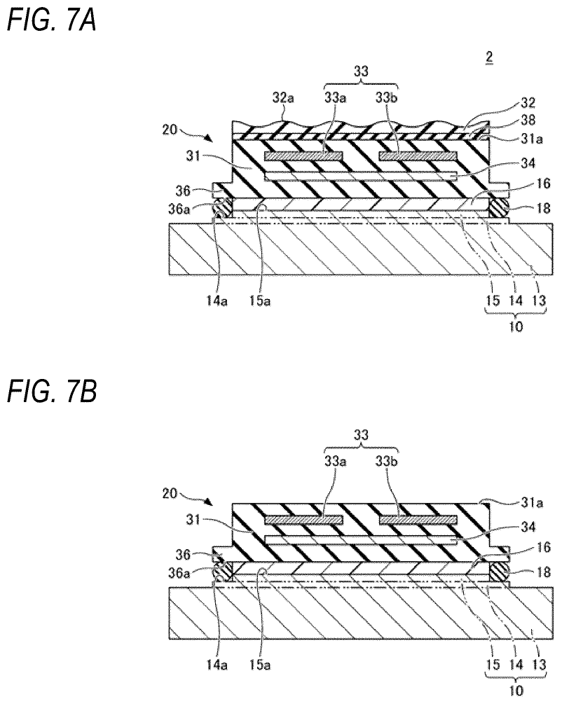

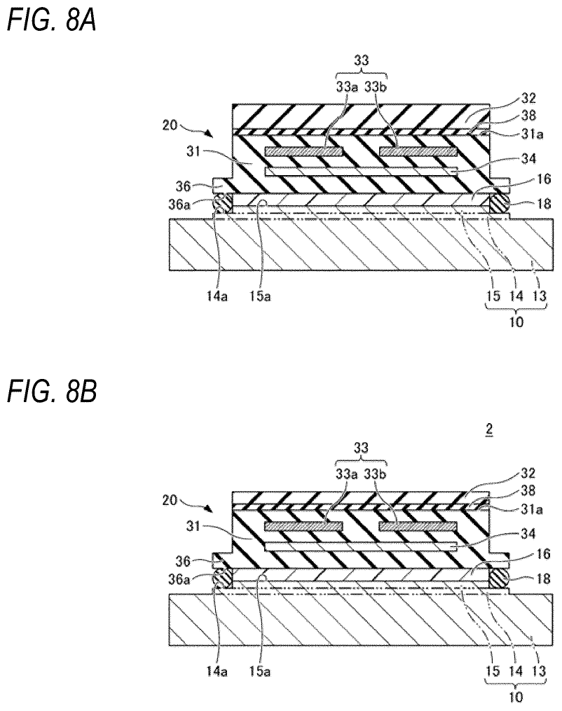

Next, a maintenance method of the substrate fixing device 2 will be described. FIGS. 7A to 8B are cross-sectional views illustrating a maintenance method of the substrate fixing device according to the second embodiment.

When the substrate fixing device 2 is used, the second ceramic substrate 32 is worn due to exposure to plasma or the like, and as illustrated in FIG. 7A, the flatness of the placement surface 32a, which is the upper surface of the second ceramic substrate 32, decreases. Therefore, for example, when the thickness of the second ceramic substrate 32 is reduced to a predetermined thickness or when the substrate fixing device 2 is used a predetermined number of times or for a predetermined time, the second ceramic substrate 32 is replaced.

Specifically, first, as illustrated in FIG. 7B, the second ceramic substrate 32 and the bonding layer 38 are grinded to expose the upper surface 31a of the first ceramic substrate 31.

Next, as illustrated in FIG. 8A, the new second ceramic substrate 32 is bonded to the upper surface 31a of the first ceramic substrate 31 using a new bonding sheet containing a glass fiber and an epoxy resin.

Next, as illustrated in FIG. 8B, the upper surface of the second ceramic substrate 32 is grinded to set the thickness of the second ceramic substrate 32 to 0.1 mm or more and 0.5 mm or less.

In this way, the second ceramic substrate 32 can be replaced and the maintenance of the substrate fixing device 2 can be performed.

According to the second embodiment, similar effects as those of the first embodiment can be obtained.

Although the preferred embodiments and the like have been described in detail, the present disclosure is not limited to the embodiments and the like described above, and various modifications and substitutions can be made to the embodiments and the like described above without departing from the scope of the claims.

What is claimed is:

1. An electrostatic chuck comprising:
a first ceramic substrate;
a conductor pattern embedded in the first ceramic substrate; and
a second ceramic substrate bonded to an upper surface of the first ceramic substrate, wherein
the first ceramic substrate contains aluminum oxide at first purity, and
the second ceramic substrate contains aluminum oxide at second purity higher than the first purity.

2. The electrostatic chuck according to claim 1, wherein
the first purity is less than 99 mass %, and
the second purity is 99 mass % or more.

3. The electrostatic chuck according to claim 1, wherein
the second ceramic substrate is in direct contact with the first ceramic substrate.

4. The electrostatic chuck according to claim 1, further comprising:
a bonding layer containing a glass fiber and an epoxy resin and configured to bond the first ceramic substrate and the second ceramic substrate.

5. The electrostatic chuck according to claim 1, wherein
a thickness of the second ceramic substrate is 0.1 mm or more and 0.5 mm or less.

6. The electrostatic chuck according to claim 1, wherein
the conductor pattern includes a conductor pattern serving as an electrostatic electrode and a conductor pattern serving as a heating element.

7. A substrate fixing device comprising:
a base plate; and
the electrostatic chuck according to claim 1 fixed to the base plate, wherein
the first ceramic substrate is between the base plate and the second ceramic substrate.
